(19) United States
(12) Patent Application Publication
(10) Pub. No.: US 2024/0093344 A1
(43) Pub. Date: Mar. 21, 2024

(54) HARD CARBON COATINGS WITH IMPROVED ADHESION STRENGTH BY MEANS OF HIPIMS AND METHOD THEREOF

(71) Applicant: Oerlikon Surface Solutions AG, Pfäffikon, Pfäffikon (CH)

(72) Inventors: Julien KERAUDY, Buchs (CH); Sebastien GUIMOND, St. Gallen (CH); Siegfried KRASSNITZER, Feldkirch (AT); Martin DRABIK, Sargans (CH)

(21) Appl. No.: 18/247,670

(22) PCT Filed: Oct. 5, 2021
(86) PCT No.: PCT/EP2021/000117

§ 371 Date: Apr. 3, 2023

Related U.S. Application Data
(60) Provisional application No. 63/087,991, filed on Oct. 6, 2020.

(51) Int. Cl. C23C 14/02; C23C 14/06; C23C 14/34; C23C 14/48

(52) U.S. Cl. CPC C23C 14/024; C23C 14/0605; C23C 14/0635; C23C 14/34; C23C 14/48

(57) ABSTRACT

A hard carbon coating and a method to improve its adhesion on components and tools subjected to high loads or subjected to extreme friction, wear and contact with other parts. The metal carbide transition layer is situated between the adhesivepromoting layer deposited directly onto the substrate surface and a top hard carbon coating. The metal carbide transition layer has a denser microstructure and improved mechanical properties in order to resist failure by spalling.

### BACKGROUND OF THE INVENTION

### Background Information

Hard carbon coatings such as hydrogenated doped (a—C:H) or hydrogen-free amorphous diamond-like carbon (DLC), often referred to as a—C or as ta—C depending of the sp³ bond fraction, are considered today as one of the most effective protective solutions for attaining improved wear resistance on surfaces of substrate tools during demanding cutting and forming operations or precision components (i.e. engine parts for the automotive sector or mechanical engineering components) operated under extreme loading conditions or subjected to extreme friction and contact pressures with other sliding partners.

High-quality hard carbon coatings deposited under appropriate thermodynamic and kinetic growth conditions by physical vapour deposition (PVD) and/or plasma assisted chemical vapour deposition (PACVD) methods are well-known to exhibit an exceptional combination of properties such as high hardness, high wear resistance in dry running and poor lubrication conditions, low friction coefficient and chemical inertness, that can be tailored very specifically (e.g. by manipulating the hydrogen content or by the selection of additional metallic and non-metallic doping elements) to meet the performance requirements of different operating conditions. Further details regarding the features and industrial applications of DLC coatings can be found in writing, among others by J. Vetter in “Surface & Coatings Technology 257 (2014) 213-240” and A. Grill in “Diamond and Related Materials 8 (1999) 428-434”.

However, the weak and unstable adhesion of DLC coatings on substrates associated with the high compressive internal stress of the layers particularly if the hydrogen-free layers are of the a—C or ta—C type can result in premature coating failures (brittle fracture, spalling and buckling) and even catastrophic film delimitation when the coating/substrate is subjected to high contact loading, hampering the lifetime and performance of the tools and components in applications.

To improve the adherence of hard carbon coatings even in a high contact load, Tashiro et al propose in US20180363128A1 to apply an adhesion improving intermediate layer on the base material before applying the hard carbon coating materials, here a hydrogen-doped amorphous carbon (a—C:H) layer having a film thickness of 1.8 μm and film hardness lower than 16 GPa by a plasma CVD method. The intermediate layer includes a Ti adhesion promoting layer deposited and a TiC layer, wherein the TiC layer is formed by a so-called reactive unbalanced magnetron sputtering method by introducing a reactive gas containing carbon (CH₄, C₂H₂) together with an inert gas (Ar) during sputtering a Ti target simultaneously. To densify the layers, a negative bias voltage is applied to the substrate to accelerate the positively charged ions to the substrate. The negative bias voltage applied in the Ti layer forming step is preferably between −200 and −300 V, while the bias voltage in the TiC layer film-forming step is preferably between −30 V and −100 V. Adhesion strength of the hard carbon/substrate was evaluated through scratch tests by measuring the critical normal load needed to occur catastrophic failure of the hard carbon/substrate. Tashiro et al found out that delamination was achieved with a load higher than 44 N and lower than 50 N. The inventors proposed to further improve the adhesion strength of the DLC layer by applying a gradient TiC layer in between the adhesion-promoting Ti layer and the TiC layer previously described, wherein the carbon content in the gradient TiC interlayer is gradually increased by controlling the flow rate ratio between the inert Ar gas and the reactive hydrocarbon CH₄ gas. The negative bias voltage applied at the substrate is simultaneously decreased from 200 to 50 V. The critical load to obtain delamination in the above-described gradient design strategy was found at value lower than 62 N.

However, the layer structure, as described above uses a two-step process using two different deposition techniques (plasma CVD and sputtering) which is complex to implement, and furthermore requires a reactive sputtering method to deposit the TiC which is usually not desirable in industry production, because the process is very sensitive to the state and age of the target used, resulting in a clear disadvantage regarding stability. In addition, to densify the Ti layer and improve the adhesion strength of the hard carbon/substrate at these low temperatures, a high negative bias voltage, typically higher than 200 V is applied to promote an effective ion bombardment at the substrate surface resulting in an ion-irradiation-induced film densification. Reducing the negative bias below 100 V results in catastrophic adhesion failure of the hard carbon/substrate since the layers sputtered in this condition have relatively low density. It is known that the strong dependence of the negative substrate bias for controlling the film density is inherently resulting from the low degree of ionization of the sputtered material flux owing to relatively low plasma densities involved during the conventional magnetron sputtering method. Conventional sputtering generally produces at the most 10% ionization of the sputtered target material; this has been described in a paper by Helmersson et al “Ionized physical vapor deposition (IPVD): A review of technology and applications”, in Thin Solid Films 513 (2006), 1-24.

It is therefore desired to have a method whereby the flux of film forming species arriving at the substrate is characterized by an increased amount of ions, since this means greater control of the deposition flux in terms of direction and energy and hence film properties such as density and stress can be tuned and optimized for the desired application, as described by Greczynski et al.,” Paradigm shift in thin-film growth by magnetron sputtering: From gas-ion to metal-ion irradiation of the growing film”, in Journal of Vacuum Science & Technology A 37 (2019), 060801.

A well-known method in the art to achieve highly ionized plasma to produce hard, dense, and wear-resistant hard carbon coatings is the vacuum arc evaporation method.

US20190040518A1 discloses a wear resistant hard carbon layer onto substrates in a vacuum chamber from a graphite cathode by a low-voltage pulsed arc. The wear-resistant hard carbon layer has a wear-resistant layer formed from tetrahedrally bound amorphous carbon (ta—C), and a titanium adhesion layer between the substrates and the wear protection layer. The adhesion promoting layer is also applied by low-voltage pulsed arc.

However, a fundamental disadvantage of arc evaporation processes is the generation and incorporation into the coatings of a large amount of macro-particles or so-called droplets which can result in severe coating defects. This disadvantage leads to an undesirable inhomogeneity in the layer, unfavorable high coating roughness, and lower coating performance. In case such hard carbons are used as tribological coating, the wear on the counter body can be unacceptably high.

It is known that methods to filter out these droplets have been proposed. For instance, WO2014177641A1 proposes a method of producing smoother wear-resistant layers of hydrogen-free tetrahedrally amorphous (ta—C) without the need of any mechanical and/or chemical machine finishing by a laser-arc method in which an electrical arc discharge is ignited in the vacuum via a pulse-operated laser beam and with which the ionized components of the plasma can be deflected toward a substrate by magnetic filters in a separate section of the coating chamber. However, the design is very complex and expensive, which makes it difficult to operate the coating process economically.

A well-known alternative approach to achieve highly ionized plasma, densities and hardness of sputtered layers similar to those achieved with the arc evaporation method without jeopardizing the surface quality is the so-called HiPIMS method (HIPIMS=high Power impulse magnetron sputtering). The industrialized process is disclosed by Krassnitzer in WO201243091A1 and described in Kouznetsov et al, “A novel pulsed magnetron sputter technique utilizing very high target power densities”, Surface and Coatings Technology 122 (1999), 290-293. In HiPIMS, highly ionized flux of the sputtered material is achieved by applying a very high peak power to the racetrack area (in cm⁻²) of the cathode target, also defined as peak power density (Pₚₑₐₖ in W.cm⁻²). As a result of the very high peak power densities, a high density plasma is achieved. In order to stay below the power limit for target/magnetron damage, the high HiPIMS power is applied in a repeated pulse fashion. In this way, the average power density (P_{Av}) is kept on a conventional magnetron sputtering level to limit the target temperature below the melting point. HiPIMS pulses are applied with a defined pulse length (tₚᵤₗₛₑ), typically in the range of few microseconds (μs) to few milliseconds (ms), and a repetition frequency typically in the range of few Hertzs to few kilo Hertzs, resulting in a duty cycle (percentage of the time the pulse is applied) typically in the range between 0.5 up to 30%.

As a result of the high pulsed power densities, a high plasma density is achieved resulting in an increased ionized fraction of the sputtered material. If a negative voltage is applied to the workpieces to be coated, these ions are accelerated towards the workpieces and consequently can be used to produce very dense coatings. This has been described by Samuelsson et al, “Influence of ionization degree on film properties when using high power impulse magnetron sputtering”, in Journal of Vacuum Science & Technology A 30 (2012), 031507.

EP2587518B1 discloses a method of depositing smooth hydrogen-free ta—C coatings on substrates of metal or ceramic materials by HiPIMS sputtering processes. In EP2587518B1, the total film thickness of the hard carbon coating has been limited to maximum 1.0 μm for coating exhibiting coating hardness above 35 GPa, obviously to limit the risk of coating adhesion failures due to the large internal internal stresses present within these hard ta—C coatings. However, in some applications, there is a further need to increase the thickness of the wear-resistant coatings to improve the fatigue, wear and impact lives of the hard material layer.

WO2008155051A1 discloses a method of depositing low-friction, wear-resistant and adherent carbon-containing PVD layers on substrate in which the substrate is pretreated in the plasma of a high-power impulse magnetron sputtering (HIPIMS) at a high negative substrate bias of −500 to −1500V and then followed by the deposition of a transition layer by HiPIMS between the substrate and the functional hard carbon-containing layer deposited by unbalanced magnetron sputtering. A second transition layer can be optionally deposited on top of the first transition layer before the growth of the functional hard carbon-containing layer. The inventors claimed that it has proved to be advantageous for the adhesion strength to use binder-free tungsten carbide WC as the target material during both the substrate pretreatment and the deposition of the transition layers. Binder-free WC targets are well-known to be considerably more expensive to manufacture than metallic targets. Taking into account that PVD typically used more than one target to gain productivity, the selection of WC as implantation and transition layer material can result in greater cost. Furthermore, the fact that the absence of a suitable target material for the growth of the transition layer can strongly limit the choice of the substrate to be coated.

Consequently, there exists a need for further processes for depositing thick hard carbon coatings which are formed from at least one hydrogen-free amorphous carbon (a—C) with high sp³ bond fraction (higher than 50%) which simultaneously exhibits a high hardness, very good sliding friction properties, and an excellent adhesion strength to the substrates and, preferably, a simpler and more flexible processes.

### SUMMARY

It is therefore an object of the present disclosure to provide a wear-resistant hard carbon coating to be applied to components and tools by HiPIMS, which has an improved film thickness and simultaneously has improved adhesion strength to the substrates, even when applied in high-stress regions.

It is a further objective of the present disclosure to provide an industrialsuited coating method for producing tools or components coated with the aforesaid high performance hard carbon amorphous coatings.

An aim of the present disclosure is attained by providing a wear-resistant hard carbon coating composition having at least a metallic adhesion promoting layer, such as Cr deposited directly onto the surface of a substrate, followed by a particular dense metal carbide transition layer produced by co-sputtering HiPIMS, such as CrxCx, and a top layer comprising a smooth, wear-resistant hard carbon layer deposited by HiPIMS sputtering of a graphite target in an inert environment. The transition layer contains a gradient coating structure with an adjustable coating microstructure that results in improved mechanical properties suitable to prevent premature coating failure of a thick hard carbon coating even under extreme loading conditions.

### BRIEF DESCRIPTION OF THE DRAWINGS

The present disclosure is further described in the detailed description which follows, in reference to the noted plurality of drawings, by way of non-limiting examples of preferred embodiments of the present disclosure.

FIG. 1 graphically illustrates the growth layout, according to an example embodiment, including the adhesion layer deposited directly onto the surface of the substrate, followed by the inventive metal carbide transition layer which is located in between the metallic adhesion layer and upper wear-resistant, smooth and hard amorphous carbon layer.

FIG. 2(a) illustrates a micrograph of a Rockwell C-indentation in a hydrogen-free hard carbon containing a state-of-the-art graded transition layer (Sample S1). FIG. 2(b) illustrates a micrograph of a Rockwell C-indentation in a hydrogen-free hard carbon containing a comparative layer (Sample S2). FIG. 2(c) illustrates a micrograph of a Rockwell C-indentation in a hydrogen-free hard carbon containing the inventive graded transition layer (Sample S3), according to an example embodiment.

FIG. 3(a) illustrates an optical micrograph of an entire scratch track in a hydrogen-free hard carbon containing a state-of-the-art graded transition layer (Sample S1). FIG. 3(b) illustrates an optical micrograph of an entire scratch track in a hydrogen-free hard carbon containing a comparative layer (Sample S2). FIG. 3(c) illustrates an optical micrograph of an entire scratch track in a hydrogen-free hard carbon containing the inventive graded transition layer (Sample S3), according to an example embodiment.

FIGS. 4(a)-(c) show TEM images of the transition layer deposited under the growth condition of the sample S1, bright field (a), HR-TEM (b), and SAED pattern (c). Black arrow indicates intercolumnar voids.

FIGS. 4(d)-(f) illustrate TEM images of the inventive interlayer deposited under the growth conditions of the sample S3, bright field image (d), HR-TEM (e), and SAED pattern (f.)

FIG. 5(a) shows Hardness HIT (a) vs carbon content of Cr₁₋ₓCₓ layers deposited under low peak power density (similar to condition used for the growth of sample S1) and with high peak power density (inventive—similar to condition used for the growth of sample S3).

FIG. 5(b) shows Elastic Modulus EIT vs carbon content of Cr₁₋ₓCₓ layers deposited under low peak power density (similar to condition used for the growth of sample S1) and with high peak power density (inventive—similar to condition used for the growth of sample S3).

FIG. 5(c) shows H³/E² ratio vs carbon content of Cr₁₋ₓCₓ layers deposited under low peak power density (similar to condition used for the growth of sample S1) and with high peak power density (inventive—similar to condition used for the growth of sample S3).

FIG. 6 shows a plot of friction coefficient vs sliding distance of a standard PECVD a—C:H vs inventive hydrogen-free a—C coating deposited by HIPIMS.

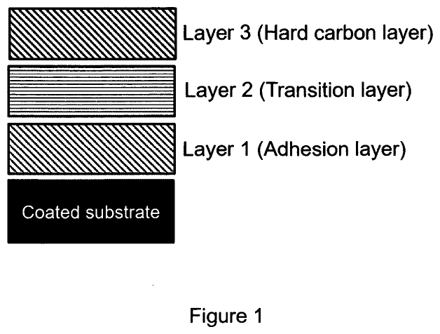

### DETAILED DESCRIPTION

The inventors have surprisingly discovered that it is possible to produce wear-resistant coatings of a hard material made of amorphous carbon with a very high hardness, and, at the same time, a very high adhesion strength to the substrate at high contact loads when a particular dense metal carbide transition layer is applied between the adhesive metal and the top amorphous layer by co-sputtering HiPIMS, in which the process parameters enhance the mobility of the ad-atoms involved in the growth of the metal carbide interlayer resulting in a densification of grain boundaries and elimination of intercolumnar voids and pores even at low growth temperature.

The term “low temperature” is used in the context of the present disclosure as temperature at the surface of the substrate of between 100° C. and 250° C., preferably between 150 and 200° C. or more preferably between 100° C. and 150° C.

As discussed above, sputtering methods can be classified in terms of duty cycle (the percentage of the time the pulse is on) and the peak power density supplied at the target racetrack. For purposes of the present disclosure, we define the term “conventional magnetron sputtering method” as a process operating where the power density of individual pulses is typically below 80 W.cm⁻² and the pulse frequency is in the range of 50 to 250 Hz. In the HiPIMS method, the power density of individual pulses is more than 500 W.cm⁻² with a duty cycle in the range of 0.5 to 15%. All discharge operations above the conventional magnetron sputtering limit and below the HIPIMS range are referred to as intermediate pulsed method. Intermediate pulsed method operates in the intermediate power density of 80-500 W.cm⁻² with a duty cycle above 15%. These definitions will be used throughout the invention.

To keep the coating system at low temperature coating processes suitable to reach optimum sp³ fraction bond fraction according to an embodiment of the present invention, the vacuum coating chamber was equipped with special protective shields which allows increasing heat dissipation in such a manner that high efficient low temperature coating process can be conducted without compromising the deposition rate, for example. The corresponding coating device is more closely described in WO2019025559. The vacuum coating chamber has no radiation heaters. However, the vacuum coating chamber can also comprise one or more radiation heaters, which can be used as heat sources for introducing heat within the chamber in order to heat the substrates to be coated.

In this way, it is possible to achieve growth of thicker hard carbon layers and to overcome the problems cited above, for example, in the application area, to produce a sufficiently thick and smooth self-lubricated hard carbon layer with improved adhesion strength at high contact load.

The present inventors have considered deposition of different metal carbide M-C(M=Cr, Ti, W, Al and Zr) transition layer. As will be discussed below, co-sputtering of at least chromium and carbon with argon as inert gas is a preferred embodiment.

According to an embodiment of the present invention, the adhesion promoting layer (layer 1) is a monolithic polycrystalline metal layer, such as Cr deposited by sputtering. To deposit the metal adhesion-promoting layer, at least one target containing Cr, for example a Cr target, is used as the Cr source, the target being operated with pulsed power in the coating chamber using a sputtering process with the inert atmosphere having at least one inert gas, preferably argon.

The electrical power supplied to the metal targets is preferentially supplied in individual pulses of a length (tₚᵤₗₛₑ) above 0.05 ms with power density and duty cycle of individual pulses preferably within the intermediate pulsed range (>50 W.cm⁻²), more preferably within the HiPIMS range (>500 W.cm⁻²). The process is usually carried out at an Ar pressure of about 0.1 to 0.6 Pa.

The negative bias voltage can be continuous, or synchronized with the HiPIMS pulses applied to the chromium targets, wherein the bias voltage is lower than −200 V, preferably lower than −100 V and further preferentially lower than −75 V.

During the deposition process, the temperature of the substrate may be maintained at a value below 200° C., preferably below 150° C. The process may be conducted without external heating.

Preferably, the total layer thickness in the Cr adhesion promoting layer is higher than 100 nm, preferably higher than 300 nm, most preferably higher than 500 nm.

To improve the load-bearing capacity of the hard carbon coating, the adhesion-promoting layer may be embodied as a multilayer coating. In this embodiment, the multilayer coating structure includes alternating individual layers of a type A and a type B. The individual layers of type A include a metal layer, such as Cr. The individual layers of type B include a hard material, such as nitride-containing (e.g., CrN) or oxynitride-containing (CrON) layers. These hard material layers can be deposited by reactive dcMS and/or HiPIMS. To deposit the nitride- or oxynitride-containing layers, at least one target containing Cr (e.g., a chromium target) is used as the Cr source. The target used for sputtering in the coating chamber is subjected to a sputtering process with the reactive atmosphere having at least one inert gas, preferably argon and at least one or a plurality of reactive gases (e.g., N₂ and O₂).

Preferably, the thickness of the individual A is not more than 500 nm and not less than 5 nm. It is also preferable that the thickness of the individual layers of type B to be not more than 500 nm and not less than 5 nm.

Preferably, the total coating thickness of the said adhesion promoting multilayer should be in the range from 0.5 μm to 10 μm, preferably between 3 μm to 5 μm.

According to an embodiment of the present invention, the transition layer (layer 2) is a graded layer having a decreasing metal content and an increasing carbon content over the thickness of the layer 2, as the distance of layer 2 from the substrate increases. In this regard, layer 2 is a compound of Cr₁₋ₓCₓ in which x is preferably as follows: 0.4<x<0.85, to avoid formation of any brittle polycrystalline Cr—C phases.

According to an embodiment of the present invention, a CrC transition layer is applied between the adhesion promoting layer and the hard carbon layer by co-sputtering. To deposit the CrC transition layer, at least one target containing Cr (e.g., a Cr target) is used as the Cr source and at least one target containing carbon (e.g., a graphite target) is used as the source of carbon. The target is used for sputtering in the coating chamber and operated with pulsed power with the inert atmosphere having at least one inert gas, preferably argon. The target containing Cr is subjected to pulsed power, preferably by a first power supply device or a first power supply unit. Also, the target containing carbon is subjected to pulsed power by a second power supply device or a second power supply unit.

With the above-described sputtering method, co-sputtering can be reliably performed in such a way that, for example, the carbon content x in Cr₁₋ₓCₓ is controlled by increasing the average power (P_{Av}) to the graphite targets, wherein the chromium targets are operated with a constant average power (P_{Av}) during the coating process.

The electrical power supplied to the graphite targets is preferentially supplied in pulses of a length (tₚᵤₗₛₑ) as less than 0.05 ms, preferably less than 0.03 ms, further preferably less than 0.01 ms with a peak power density and duty cycle of individual pulses preferably within the intermediate pulsed method range (>50 W.cm⁻²).

The inventors surprisingly found that a key requirement for producing the inventive CrC transition layer is to attain growth conditions with a sufficient high adatom mobility on the growth front. That is, by exposing high fluxes of ionized Cr species to the growing CrC films by applying to chromium targets pulses of a length (tₚᵤₗₛₑ) above 0.05 ms with a power density and duty cycle of individual pulses in the range of HiPIMS method (>500 W.cm⁻²). Ion irradiation with Cr⁺ ions onto the surface of the growing CrC transition layer dynamically enhances surface and subsurface diffusion of the adatom film species (C and Cr) before being incorporated into the bulk film, which results from direct transfer of kinetic energy to atoms close to the ion impact site by the bombarding ionized Cr species. The metal-ion irradiation induced surface adatom mobility favors film densification and clear reduction of intercolumnar porosity and voids typically observed for example in conventional coating processes by magnetron sputtering at this low temperature. It is known that these defects can act as nucleation sites for crack propagation causing early fracture and ultimately catastrophic delamination. While not wishing to be bound by theory, it is believed that the film densification at lowtemperature offers unprecedented opportunities for the development of improved damage-resistant transition layer with advantageous mechanical properties (high hardness and elastic modulus), thereby contributing to an effective fracture toughness enhancement as more energy is required to initiate and propagate cracks of various sizes, and thus suppressing the driving force for crack growth through stress-induced decohesion at the sharp interface associated with the high compressive internal stress of the hard carbon layer. The smooth transition in composition and mechanical properties between the adhesion-promoting layer and the hard carbon layer through the application of this inventive transition layer also tends to improve interfacial bonding and reduce elastic modulus mismatch between these two layers, thereby facilitating the deposition of welladhered thick hard carbon coatings with improved performance under extreme loading conditions or subjected to extreme friction and contact pressures with other sliding partners.

During the deposition process, the temperature of the substrate may be maintained at a value between 100° C. and 250° C., preferably between 150 and 200° C. or more preferably between 100° C. and 150° C. The process may be conducted without external heating.

In preferred embodiments, the process is carried out at an Ar pressure of about 0.1 to 0.6 Pa.

According to a further preferred embodiment of the present invention, the sufficiently high adatom mobility is achieved by applying a negative bias at the substrate. The bias voltage can be continuous or synchronized with the HiPIMS pulses applied to the chromium targets, wherein the bias voltage has a value higher than 20 V, further preferentially higher than 50 V, especially preferred higher than 100 V. The inventors surprisingly found that a thickness of between 10 nm to 300 nm of the abovementioned transition layer was enough for promoting excellent adhesion strength of the hard carbon/substrate.

According to another embodiment of the present invention, the hard carbon layer (layer 3) comprises at least one hydrogen-free amorphous carbon layer (aC) deposited by pulsed power. To deposit the at least hydrogen-free amorphous layer, at least one target containing C (e.g., a graphite target) is used as the C source. The target is used for sputtering in the coating chamber and operated with pulsed power with the inert atmosphere having at least one inert gas, preferably argon.

The electrical power supplied to the graphite targets is preferentially supplied in pulses with lengths (tₚᵤₗₛₑ) as less than 0.05 ms, preferably less than 0.03 ms, particularly preferably less than 0.01 ms, with peak power density and duty cycle preferably in the range of intermediate pulsed methods, more preferably in the range of HiPIMS methods, for achieving a highly ionized Ar plasma to promote the growth of highly dense, hard, smooth and free of droplets amorphous carbon.

In preferred embodiments, the process is carried out at an Ar pressure of about 0.1 to 0.3 Pa.

The negative bias voltage can be continuous, or synchronized with the HiPIMS pulses applied to the graphite targets, wherein the bias voltage value is between −50 V and −150 V, more preferably between −50 V and −100 V.

During the deposition process, the temperature of the substrate may be kept at less than 150° C., most preferably less than 120° C., and further preferred even at less than 100° C. The process may be conducted without external heating.

The hardness of the hydrogen-free amorphous is preferably higher than 30 GPa. The preferred range for the hardness of the amorphous carbon layer is between 30 GPa and 40 GPa.

The elastic modulus of the hydrogen-free amorphous layer is preferably higher than 250 GPa. The preferred range for the elastic modulus of the amorphous carbon layer is between 250 and 300 GPa.

The fraction of the sp³ bonded carbon of the hydrogen-free amorphous carbon is preferably higher than 30% further preferably higher than 50% for example between 30% and 60%.

Preferably, the said at least one hydrogen-free amorphous carbon exhibits a very smooth surface characterized by Rz<0.5 μm.

Preferably, the argon concentration in the said at least one hydrogen-free amorphous carbon layer is preferably lower than 10 at. %, as for example 5 at. %.

Preferably, the electrical resistivity of the said at least hydrogen-free amorphous carbon layer is lower than 10⁻³ Ω·cm⁻¹, preferably lower than 10⁻⁴ Ω·cm⁻¹.

Preferably, the hydrogen-free amorphous carbon layer has an anthracite gray value L* between 50 and 55 (according to the CIE 1976 L* a* b* color space based on a D65 standard illumination)

Preferably, the wear rate of the said at least hydrogen-free amorphous carbon layer is lower than 3.0.10⁻¹⁶ m³/Nm.

Preferably, the total thickness in the said at least one hydrogen-free amorphous carbon layer is higher than 0.1 μm, preferably higher than 1.0 μm, most preferably higher than 2.0 μm.

According to another embodiment, the hard carbon layer may comprise at least a metal-doped amorphous carbon layer (a—C:Me) layer which contains at least one metal (Me=Cr, Ti, W, Al and Zr). To provide the metallic element for forming the at least a—C:Me layer, at least one target comprising Me is used. In one embodiment, the at least one target can be subjected to arc evaporation, conventional sputter, or HiPIMS methods. The addition of metal in a—C:Me can be expected to reduce the internal compressive stress of the coating, improving the resilience and wear resistance for particular tribological wear phenomena, like for instance high temperature wear, impact fatigue wear, as is generally known to a person skilled in the art.

Preferably the content of metal in the metal-doped amorphous carbon layer is preferably lower than 10 at. %, as for example 5 at. %. The minimum content of metal in the metal-doped amorphous carbon layer is 1 at. %.

The hardness of the metal-doped amorphous layer is preferably higher than 20 GPa. The preferred range for the hardness of the a—C:H layer is between 20 GPa and 40 GPa.

According to another embodiment, the hard carbon layer may comprise a layered structure with a hydrogen-doped amorphous carbon (a—C:H) deposited on top of the hydrogen-free amorphous carbon sublayer by reactive HiPIMS. During the deposition of the a—C:H layer, the reactive atmosphere comprises one inert gas, preferably argon, and at least one hydrocarbon gas (CH₄, C₂H₂, C₇H₈, . . . ), preferably C₂H₂, is used as the reactive gas. During this process, the electrical power supplied to the graphite targets is subjected in the same manner as specified above for the production of the hydrogen-free carbon layer. This top a—C:H layer can positively influence the running-in wear behaviour of the hard carbon coating in applications with sliding surfaces.

In preferred embodiments, the process is carried out at a total pressure of about 0.1 to 0.6 Pa.

In one embodiment of the hydrogen-doped amorphous carbon (a—C:H), the hydrogen concentration is preferably lower than 30 at. % such as 20 at. %. Preferably, the hydrogen-doped amorphous carbon layer is applied as a gradient layer on top of the hydrogen-free amorphous carbon, wherein the concentration of hydrogen increases toward the gradient surface.

The hardness of the hydrogen-doped amorphous carbon layer is preferably higher than 20 GPa. The preferred range for the hardness of the a—C:H layer is between 20 GPa and 40 GPa.

Preferably, the hydrogen-doped amorphous carbon layer has a black appearance with L* value between 40 and 50.

Preferably, the layer thickness of the said hydrogen-doped amorphous carbon layer accounts for 30% of the total layer thickness of the hard carbon layer, but is not limited to this amount.

According to another embodiment, it is also possible to dope a—C with another non-metallic elements (generally identified as X) for layer optimization depending on the application. For example, doping N or Si in a—C results in a reduction of stress as well as friction while doping with F results in a change in wetting properties (higher wetting angle), as is generally known to a person skilled in the art. These non-metallic elements can be nitrogen, boron, silicon, fluorine, or others. The element X can be supplied from the precursors in gas phase (Si-containing precursors like silane, HDMSO, TMS, fluorocarbon gases CF₄, . . . ) or from graphite targets that are alloyed with the X element.

Preferably, the content of non-metal in the non-metal doped amorphous carbon layer (a—C:X) is lower than 30 at. %, preferably lower than 20 at. %, more preferably lower than 10 at. %. The minimum content of non-metal in the non-metal doped amorphous carbon layer (a—C:X) is 1 at. %.

Preferably, the hardness of the non metal-doped amorphous layer (aC:X) is preferably higher than 20 GPa. The preferred range for the hardness of the aC:X layer is between 20 GPa and 40 GPa.

Carbon coating according to an embodiment the present invention can be used to coat any metal workpieces, either flexible or rigid, composed of steel substrates, hard metal substrates, such as cobalt-cemented tungsten carbide; aluminium or aluminium alloy substrates, titanium or titanium alloy substrates or copper and copper alloy substrates. Since the temperature for the manufacture of the wear-resistant carbon-based coating, according to the present disclosure can be as low as 100° C., it is possible to coat temperature-sensitive substrates.

In embodiments, is possible to coat machining tools and forming tools. The carbon coating according to an embodiment of the present invention is applied on valve train components such as tappets, wrist pins, fingers, finger followers, camshafts, rocker arms, pistons, piston rings, gears, valves, valve springs and lifters. Components such as household appliances such as knives, scissors, and razor blades, medical components such as implants and surgical instruments, and decorative parts such as watch cases, crowns, bezels, bracelets, buckles, among other things can also be coated with the carbon coating according to embodiments of the present invention.

A preferred embodiment of the present invention will now be explained in detail and by way of example with reference to a process description.

### EXAMPLE

### Example 1

In order to produce the carbon coating according to an embodiment of the present invention, workpieces made of steel with hardness of 62 HRC were placed in an Oerlikon Balzers INLENIA Pica vacuum processing chamber equipped with at least three targets of chromium and at least three targets of graphite, whereupon the vacuum chamber was pumped down to a pressure of about 10⁵ mbar.

In order to demonstrate the effectiveness of interposition of a particular dense metal carbide transition layer in between a metal adhesion-promoting layer and a thick hard carbon layer according to an embodiment of the present invention, three samples with different transition layers were deposited with identical parameters for all remaining process steps, including the deposition of the metallic adhesion-promoting layer and the hydrogen-free amorphous carbon.

As a first part of the process, a plasma heating process is carried out for 30 minutes in order to bring the substrates to be coated to a higher temperature of approximately 200° C. and to remove volatile substances from the surface of the substrate and the vacuum chamber walls being sucked out by the vacuum pump. In this pretreatment step, an Ar hydrogen plasma is ignited by a low-voltage arc (LVA) between the ionization chamber and an auxiliary anode.

After 10 minutes of cooling, the steady-state temperature inside the chamber has dropped down to 100° C. due to the high efficient heat dissipation of the protective shields as previously mentioned. An Ar ion plasma etching process of 20 minutes duration is initiated by activating the low voltage arc ionization chamber and an auxiliary anode. The Ar ions are drawn from the low voltage arc plasma by a negative bias voltage of 120 V onto the substrates to be cleaned with the primary goal to remove impurities such as native oxides or organic impurities via ballistic removal (i.e., native oxides and impurities are sputtered etch by the intense Ar* ion bombardment) to ensure a good layer adhesion of the adhesive metal layer that takes place after the ion cleaning.

As the next procedural step, a 300 nm-thick adhesion-promoting layer Cr layer is deposited by the HiPIMS method, according to an embodiment of the present invention, directly onto the surface of the substrate to be coated using the following process parameters: a power density of individual pulses of 700 W.cm⁻², an Ar total pressure of 0.3 Pa, and a constant bias voltage of −50 V at a coating temperature lower than 180° C. for 30 minutes.

During this time, three chromium targets were subjected to process steps specified above.

Then, immediately afterward, a 200 nm-thick graded CrC transition layer was deposited in accordance with an embodiment of the present invention by a co-sputtering method. In this method, the three chromium targets were subjected as before, but with different settings. In addition, three graphite targets were added. For all samples, the three graphite targets were subjected to an average power Pₐᵥ starting from 80 W.cm⁻² to 161 W.cm⁻² in order to gradually increase the C content, wherein the chromium targets were subjected to a constant average power Pₐᵥ of 20 W.cm⁻². The power density and duty cycle of the individual pulses supplied to the graphite targets were within the intermediate pulsed method range in accordance with an embodiment of the present invention. Regarding the chromium targets, the power density of the individual pulses has been modified for each sample in order to attest the impact of the metal-ion irradiation. The following three different power densities were selected: 20 W.cm⁻², 70 W.cm⁻², and 600 W.cm⁻².

The associated samples are listed in the sequence as sample S1 (CrC deposited with a low Cr peak power of 20 W.cm⁻²), sample S2 (CrC deposited with an intermediate power pulse of 70 W.cm⁻², and sample S3 (CrC deposited by a high peak power of 600 W.cm⁻² according to an embodiment of the present invention).

The settings used for the sample S1 correspond to what is known in the prior art as conventional magnetron sputtering. The power density values were less than 50 W/cm⁻². Sample S1 and sample S2 serves for comparison purposes with regard to layer properties and adhesion strength.

For these three transition layers, the working pressure was always kept at 0.3 Pa, with a constant bias voltage of −50 V at a substrate temperature lower than 150° C. for 30 minutes.

The chemical composition of these three graded CrC transition layers was measured by energy-dispersive X-ray spectroscopy (EDX). Analysis indicated that the C content increases over the thickness of the transition layer, as the distance from the substrate increases. In this regards, the C content within the graded CrC transition layers for all the associated samples ranged from 40 at. % to 85 at. %.

X-ray diffraction measurements together with high-resolution transmission electron microscopy (TEM) analysis revealed that these two graded CrC transition layers exhibited an amorphous/nano-crystalline structure with only some cluster of ordered carbide arrangement (<1-2 nm) present. The absence of long-range order carbide grains or also called nanocomposite microstructure can be due to the low temperature conditions (<200° C.) applied during the transition layer film growth. The amorphous/nano-crystalline structure is also supported by XRD diffractograms revealing only a broad feature originating from local ordering around single atoms.

Finally, a 2.0 μm-thick wear-resistant hydrogen-free a—C layer with a coating hardness of 40 GPa and an elastic modulus of 290 GPa (measured with a load of 10 mN on a Fischerscope Instruments) was deposited on top of transition layers by a HiPIMS method according to an embodiment of the present invention using the following parameters: a power density of individual pulses of 500 W.cm², with a tₚᵤₗₛₑ of 0.05 ms, at a total pressure of 0.3 Pa and a constant bias voltage of −100 V at a coating temperature of 120° C. for a total deposition duration of 360 minutes.

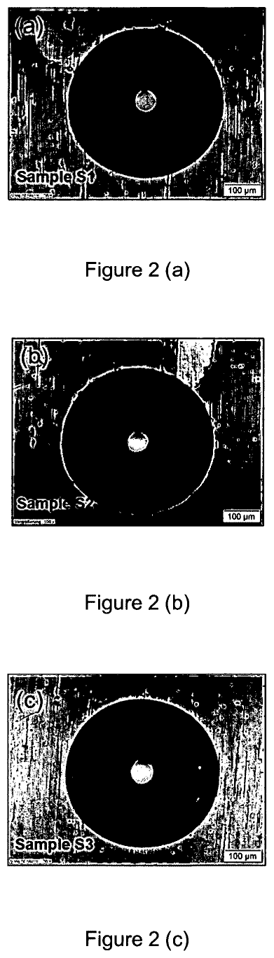

In order to ascertain adhesion strength of these two samples, the adhesion class of both coatings was evaluated by the Rockwell C method (HRC process) with a load of 150 kg and is presented in FIG. 2. According to the VDI 3198 standard, the adhesion of the coating is obtained by using an optical microscope and divided into six classifications, starting from HF1 (very good adhesion) to HF6 (poor adhesion), according to the level of cracking and coating delamination around the indent.

Despite the application of an identical adhesion-promoting layer and hard carbon layer on top, it surprisingly turned out that a considerable improvement in the adhesion strength of the hard carbon-substrate was found in sample S3 that comprised a graded CrC transition layer deposited at high power density of individual pulses according to embodiments of the present disclosure in comparison to the sample S1 or even S2 that comprised a graded CrC transition layer deposited at lower power density of individual pulses according to other references.

FIG. 2. (a) shows the photograph of a Rockwell C indentation onto the surface of the sample S1. FIG. 2. (b) shows the photograph of a Rockwell C indentation onto the surface of the sample S2. FIG. 2. (c) shows the photograph of a Rockwell C indentation onto the surface of the sample S3 with a graded CrC transition layer according to an embodiment of the present invention.

In samples S1 and S2, the carbon coating exhibits a large field of delamination around the indentation, resulting in a classification of poor adhesion strength quality HF 6. Spontaneous delamination was also observed for the sample S1 at the edges of the sample due to the high internal stress build-up resulting from the edge effects. Thus, to avoid spontaneous delamination at coated edges, the hard carbon coating thickness must be reduced to a value below 1 μm.

In clear contrast, the carbon coating in sample S3, according to the innovative transition layer, exhibits no visible delamination around the indentation crater and remains nearly crack-free after indentation, typical of an excellent adhesion strength quality HF1.

To further ascertain adhesion strength of all three samples, scratch tests were performed with a Rockwell C diamond stylus (0.2 mm in radius) according to the ISO 20502:2016. The applying load was linearly increased from 10 to 75 N on a scratch length of 6 mm with a loading rate 10 N/mm. Each scratch test was repeated 3 times for each coating. To avoid any major source of error, diamond stylus are always inspected prior each scratch test to check for damage or contamination. The critical loads to induce cohesive and/or adhesive failure of the coating-substrate were assessed by optical microscopic observations with a magnitude of 200. The critical loads were determined at which the first visible cracks appearing in the scratch channel (Lc1), the film delaminates alongside the scratch (Lc2), and the catastrophic adhesive failure of the coating (Lc3) occurs. It is known that Lc3 is a good indicator to evaluate the adhesion strength of the coating/substrate.

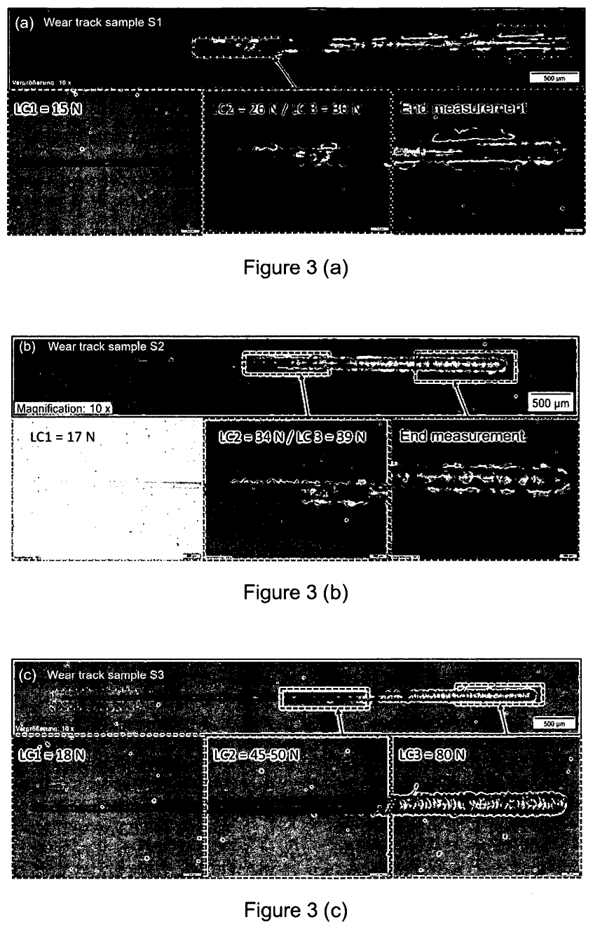

A comparison of scratch tests of S1, S2 and S3 can be found in FIG. 3. FIG. 3. (a) shows the optical micrograph of the scratch track as well as close up micrographs of the failure mechanisms for S1. FIG. 3.(b) shows the optical micrograph of scratch track as well as close up micrographs of the failure mechanisms for sample S2. FIG. 3.(c) shows the optical micrograph of scratch track as well as close up micrographs of the failure mechanisms for sample S3. For sample S1, cracks start to appear with critical load values of Lc1 15+/−3 N, a brittle delamination is observed for a critical-load values of Lc2 of 26+/−3 N with extensive cracking and interfacial separations extending over the side of the scratch track resulting from a weak cohesive strength inside the CrC interlayer near the CrC/a—C interface. Catastrophic failure of the coating happens at a critical load Lc3 of 30+/−3 N. Same failure mechanism seems to occur during the scratch test of the sample S2 but at higher critical loads, critical load values of Lc2 is found at 34 N and Lc3 at 39 N.

For sample S3 with the innovative CrC transition layer, cracks nucleates at critical load values of 20+/−2 N, while tensile buckling spallation along the scratch track was detected for a contact load Lc2 of 48+/−5 N. Surprisingly, no catastrophic adhesive failure of the coating/substrate was noticed even at a critical load up to 75 N, which demonstrates an excellent adhesion strength of the coating/substrate and an enhanced damage-resistance capability of the innovative transition layer, in excellent agreement with the Rockwell C method.

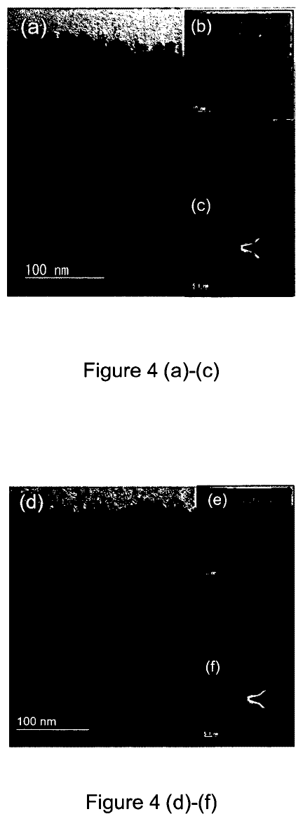

To understand the mechanism for the improved adhesion strength of the sample S3, a comparison of the microstructure of the graded CrC interlayer that applied on the sample S1 and S3 was carried out through cross-section transmission electron microscopic (TEM) observations. The results are presented in FIG. 4. FIG. 4. (a) is a cross-sectional TEM micrograph of a graded CrC transition layer applied onto sample S1 grown at low peak power density Pₚᵤₗₛₑ. A pronounced columnar structure with conical upper surfaces and an average column width of 10+/−5 nm is observed with inter-columnar and intra-columnar porosity, best seen in the high resolution TEM micrograph (b), which is a signature of a low adatom surface mobility growth regime at low temperature process (Ts<150° C.) for conventional magnetron sputtering method. The selected area diffraction (SAED) pattern, see TEM image (c), representing the diffraction signal from an area of around 150 nm of the CrC interlayer shows no indication for periodical long-range of either Cr or CrC grains, but instead exhibits an amorphous structure.

In clear contrast, the innovative graded CrC transition layer on the sample S3 grown at very high peak power density Pₚᵤₗₛₑ exhibits a much denser microstructure with an average column width of 50+/−10 nm, accompanied by a drastic reduction of the intercolumnar voids, as revealed by the cross-sectional TEM image (see FIG. 4.(d)), and confirmed by the high-resolution TEM observation (see FIG. 4.(e)), and the column tops become rounded with much shallower groves. The SAED pattern of the innovative CrC transition layer (see FIG. 4. (f)), reveals no structural changes in comparison to the sample S1.

While not wishing to be bound by theory, it is believed that the observed film densification at low temperature results from the intense Cr⁺ ion bombardment produced at the Cr targets during the very high instantaneous high-power pulses and accelerated toward the growing CrC transition layer using the negative bias voltage. The metal ion bombardment dynamically enhances near-surface atomic mixing during the film growth by providing additional kinetic energy to the adatoms (C and Cr), thereby inducing higher surface mobility before being incorporated into the bulk film to eliminate the inter- and intra-columnar porosity typical of low-deposition temperature and thus increases the cohesion strength of the transition layer. Cr⁺ ions are incorporated in the coating layers without causing any lattice distortion, instead of gas ions such as Ar*.

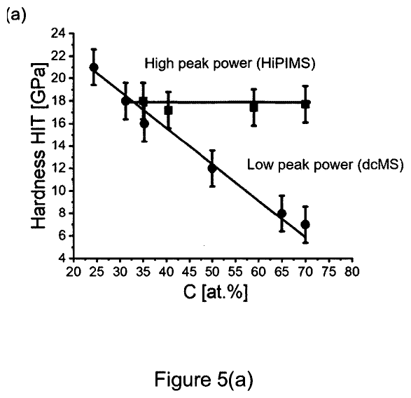

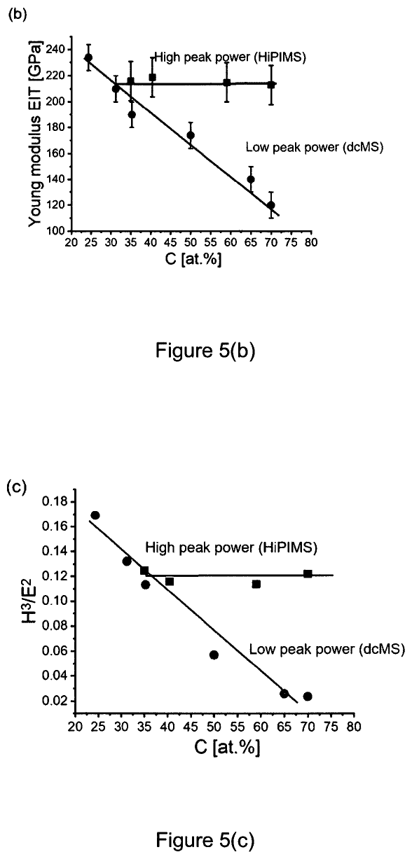

Microstructure densification caused by Cr⁺ ion irradiation quite unexpectedly demonstrated a beneficial effect on enhanced mechanical properties of the graded CrC transition layer, as shown in FIG. 5. (a)-(c), where microindentation hardness HIT (in GPa), elastic modulus EIT (in GPa) and the H³/E² ratio, reflecting materials resistance to plastic deformation or toughness of individual Cr₁₋ₓCₓ layers grown with the exact same process parameters as sample S1 and sample S3, were plotted as a function of C content, over the range 0.3<x<0.7. All layers had a total film thickness of about 1.0 μm.

For Cr₁₋ₓCₓ layers grown under low peak power density Pₚᵤₗₛₑ (S1-20 W.cm⁻²), a rapid decrease in HIT is observed, from 18 GPa with x=0.3 to, 12 GPa and 7 GPa with x=0.5 and 0.7, respectively. In a similar way, EIT drops from 210 GPa at lower x values to 180, 140 and even 110 GPa with x=0.5, 0.6 and 0.7, respectively. The H³/E² ratio drops from 0.13 at lower x values to 0.02 with x=0.7.

Surprisingly, enhanced mechanical properties are obtained for Cr₁₋ₓCₓ layers grown under high peak power density Pₚᵤₗₛₑ (S3-700 W.cm⁻²) where HIT is high, 18 GPa, even for x=0.7. Stable EIT=215 GPa with x in the range from 0.35 to 0.7, which is almost 50% higher than the corresponding Cr₁₋ₓCₓ films grown at low peak power density at higher x values. In a similar manner, H³/E² ratio reflecting material toughness stays relatively constant in the level of 0.12 even for x as high as 0.7, a factor of x6 higher value than measured for Cr₁₋ₓCₓ layers with similar C content grown at low peak power density.

While not wishing to be bound by theory, it is believed that the enhanced toughness of the graded CrC transition layer grown under a high peak power density Pₚᵤₗₛₑ (S3-700 W.cm⁻²) can accommodate a higher strain against plastic deformation in the transition layer and at the interfaces, e.g., Cr/Cr₁₋ₓCₓ (the innermost interface at lower x values) and hard carbon layer/Cr₁₋ₓCₓ (the outermost interface at higher x values), thereby reducing the probability for cracking and fracture failures during loading and unloading, and thus improving the adhesion strength of the hard carbon/substrate even under high loading conditions.

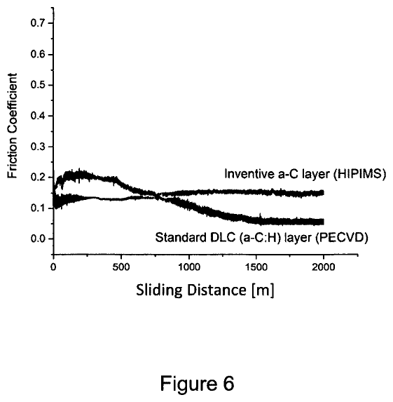

The friction of the inventive hard carbon coating composition with the CrC transition layer grown under high peak power density Pₚᵤₗₛₑ (S3-700 W.cm⁻²) was tested using the pin-on-disk test (pin-on-disk tribometer, CSC Instruments). The test was performed in air under dry condition at a temperature of 22° C. and 43% relative humidity. The sample was abraded against an uncoated 100Cr6 steel ball with a diameter of 3 mm. The steel ball served as a static friction partner and the coated sample was turned underneath it (radius 6 mm, speed 0.3 m/s). A 10 N load was applied on the ball. This corresponds to an instantaneous contact pressure of 2.2 GPa applied onto the surface of the hard carbon layer. The measurement of the inventive coating was compared to a 2.5 μm-thick hydrogen-doped a—C:H DLC coatings with a coating hardness of 20 GPa and deposited by plasma-enhanced chemical vapour deposition (PECVD) method. Representative friction coefficient after 2000 meters for both coatings are plotted in FIG. 6.

Surprisingly, the running in characteristic of the inventive layer turned out to be slightly better as compared to the standard PECVD DLC layer. As can be seen from the FIG. 6, the friction coefficient of the inventive coating seems to be slightly above the friction coefficient of the PECVD DLC layer. It is known that doping the a—C film with hydrogen can help to reduce the friction coefficient in dry condition. Very surprisingly, however, was the fact that the inspection of the abraded surfaces after the test show significantly less layer and slightly less counterpart component wear in general for the inventive layer than for standard PECVD layer (width of the abrasion part of the coating 150 μm vs 300 μm, diameter of the abraded area on the ball 400 μm vs 450 μm), demonstrating the enhanced wear-resistant properties of the inventive hard carbon coating composition. One possible explanation for this surprisingly lower abrasion wear on the uncoated counter-body ball could be due to the smoothness and lowdefect density provided by this a—C layer deposited by HiPIMS.

Further, at least because the invention is disclosed herein in a manner that enables one to make and use it, by virtue of the disclosure of particular exemplary embodiments, such as for simplicity or efficiency, for example, the invention can be practiced in the absence of any additional element or additional structure that is not specifically disclosed herein.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

Disclosed is a hard carbon coating composition with improved adhesion strength when applied onto a substrate, comprising:
an adhesion layer in direct contact with a surface of the substrate;
a metal carbide transition layer that is deposited onto the adhesion layer; and
a hard carbon layer that is deposited onto the carbide transition layer.

The adhesion layer of the hard carbon coating composition can be a monolithic polycrystalline metal layer.

The the monolithic polycrystalline metal layer can comprise Cr.

The adhesion layer can have a thickness of 0.1 μm to 10 μm.

The adhesion layer can be a multilayer coating comprising alternating individual layers of a type A and a type B,
wherein the type A comprises a metal layer, and
wherein the type B comprises a nitride-containing layer or an oxynitride-containing layer.

The metal layer can comprise Cr.

The metal carbide transition layer can comprise M-C, wherein M represents at least one of Cr, Ti, W, Al, and Zr, and wherein C represents carbon.

The metal carbide transition layer can comprises a compound of Cr₁₋ₓCₓ, wherein x represents 0.4<x<0.85.

The metal carbide transition layer can be a graded layer having a metal content that decreases and a carbon content that increases over the thickness of the metal carbide transition layer as the distance from the substrate increases.

The carbon content within the metal carbide transition layer can range from 40 at. % to 85 at. %.

The metal carbide transition layer can have a microstructure with an average column width of 50+/−10 nm with reduced intercolumnar voids.

The metal carbide transition layer can have a thickness of 10 nm to 300 nm.

The hard carbon layer cank comprise at least one hydrogen-free amorphous carbon layer (a—C).

The hard carbon layer can have a hardness of 30 GPa to 40 GPa.

The at least one hydrogen-free amorphous carbon layer can have a thickness of at least 0.1 μm.

The hard carbon layer can comprise a metal-doped amorphous carbon layer (aC:Me) layer, said metal-doped amorphous carbon layer comprising at least one of Cr, Ti, W, Al and Zr.

The metal-doped amorphous carbon layer can have a metal content lower than 10 at. %.

The hard carbon layer can be a layered structure having a hydrogen-doped amorphous carbon (a—C:H) deposited onto a hydrogen-free amorphous carbon sublayer.

What is claimed is:

1. A method for producing a metal carbide transition layer on a substrate, comprising:
a deposition process thereby ion irradiating Cr⁺ ions onto a surface by applying to at least one Cr target pulses of a length (tₚᵤₗₛₑ) above 0.05 ms with a power density of greater than 500 W.cm⁻².

2. The method according to claim 1 characterized by maintaining the temperature of the substrate at a value between 100° C. and 250° C.

3. The method according to claim 1, characterized in that the process is conducted without external heating.

4. The method according to claim 1, characterized in that Ar is used as working gas in the process and the process is carried out at an Ar pressure of about 0.1 to 0.6 Pa.

5. The method according to claim 1, characterized in that during the process a negative bias is applied to the substrate.

6. The method according to claim 5, characterized in that the bias is synchronized with the pulses.

7. The method according to claim 5, characterized in that the bias voltage reaches values higher than 20 V.

8. The method of coating a carbon composition, comprising the steps of:
coating an adhesion layer in direct contact with a surface of the substrate
depositing a metal carbide transition layer onto the adhesion layer; and
depositing a hard carbon layer onto the carbide transition layer, characterized in that the carbon transition layer is deposited onto the adhesion layer using a method according to claim 1.

9. A method for producing a tool or a component with a hard carbon coating, comprising: applying the hard carbon coating composition according to claim 1 onto the tool or the component.

10. The method according to claim 1 characterized by maintaining the temperature of the substrate at a value between 100° C. and 150° C.

11. The method according to claim 5, characterized in that the bias voltage reaches values higher than 50 V.

12. The method according to claim 5, characterized in that the bias voltage reaches values higher than 100 V.
